(19) United States
(12) Patent Application Publication
(10) Pub. No.: US 2026/0002287 A1
(43) Pub. Date: Jan. 1, 2026

(54) PROCESS FOR DIVIDING SINGLE-CRYSTAL SUBSTRATES

(71) Applicant: MITSUBOSHI DIAMOND INDUSTRIAL CO., LTD., Osaka (JP)

(72) Inventors: Naoya KIYAMA, Settsu City (JP); Mitsuru KITAICHI, Settsu City (JP); Akira MORI, Settsu City (JP); Masakazu TAKEDA, Settsu City (JP)

(21) Appl. No.: 19/321,822

(22) Filed: Sep. 8, 2025

Related U.S. Application Data
(63) Continuation of application No. PCT/JP2024/010033, filed on Mar. 14, 2024.

(30) Foreign Application Priority Data
Mar. 23, 2023 (JP) 2023-046787

(51) Int. Cl. C30B 33/00; C30B 29/36

(52) U.S. Cl. CPC C30B 33/00; C30B 29/36

(57) ABSTRACT

A process for dividing a single-crystal substrate having a cleavage plane inclined with respect to a scribe-surface and a break-surface of the single-crystal substrate is provided. The process includes steps of forming a scribe line on the scribe-surface, attaching an adhesive dicing tape onto the scribe-surface, inverting and placing the single-crystal substrate on a breaking table such that the scribe-surface faces the breaking table, bringing a breaking plate into contact with the break-surface along a break-line which is positioned away from a cross-line where the cleavage plane extending from the scribe line crosses the break-surface, with respect to a reference line where a vertical plane extending from the scribe line in a direction orthogonal to the scribe-surface and the break-surface crosses the break-surface, and applying external force to the break-surface from the breaking plate to divide the single-crystal substrate along the cleavage plane.

### CROSS REFERENCE TO RELATED APPLICATIONS

This application is a continuation application of International Application No. PCT/JP2024/010033, filed on Mar. 14, 2024, which claims the benefit of priority to Japanese Patent Application No. 2023-046787, filed on Mar. 23, 2023. The entire contents of each of these applications are hereby incorporated herein by reference.

### BACKGROUND OF THE INVENTION

### 1. Field of the Invention

The present invention relates to a process for dividing single-crystal substrates.

### 2. Description of the Related Art

Conventionally, as shown in FIG. 1, in a process for manufacturing semiconductor devices by dividing a single-crystal substrate 1 having cleavage property such as SiC and Si into the semiconductor devices, the single-crystal substrate 1 includes a scribe-surface 3 which is attached to an adhesive side of a dicing tape 9 (wafer fixing tape), and a break-surface 2 opposite to the scribe-surface 3, which is protected by a non-adhesive side (including a slightly adhesive side) of a protecting film 10. Thus, the single-crystal substrate 1 has a top side kept in an unbound state on the protecting film 10.

The single-crystal substrate 1 is placed on a breaking table 11 with a bottom of the single-crystal substrate 1 attached to the dicing tape 9. A camera 12 is provided below the breaking table 11, which is configured to detect the scribe lines L formed on the single-crystal substrate 1.

A breaking plate 13 having a blade 14 at its tip is lowered onto and brought into contact with the single-crystal substrate 1 from the break-surface 2 or the top side opposing to the scribe lines L, and further pushed downward with an external force to break or divide the single-crystal substrate 1 into semiconductor devices. The techniques for dividing the substrate are disclosed, for example, in Patent Documents 1, 2 and the like.

Patent Document 1, which is JP H05(1993)-055373 A, has an objective to provide a method for uniformly dividing a wafer having a crystal orientation oblique to its surface, by pushing upward the wafer with a blade along the dicing line on the surface and cracking the wafer. Namely, Patent Document 1 discloses a cracking process and apparatus to diagonally divide the wafer, in a reliable manner, which includes the crystal orientation oblique to the surface into a plurality of chips, without cracks in the chips or cracks in misaligned locations causing the chips on both sides of the crack to be defective, in a reliable manner.

Patent Document 2, which is JP 2020-070202 A, has an objective to provide a method for dividing a laminated substrate encapsulating a seal member having a cell area, an intermediate end-material area, and a boundary portion defined therebetween, in which a break bar contacts onto the laminated substrate at a position where the intermediate end-material area is located and shifted from the scribe line to the cell area, such that shape defects on side edges of the substrate are reduced. Thus, Patent Document 2 aims to appropriately divide the laminated substrate encapsulating the predetermined seal member at the portion where the seal member exists.

First, the following describes a mechanism for breaking or dividing a single-crystal substrate 1.

As illustrated in FIG. 2, depending on objectives and manufacturing processes of semiconductor products, a single-crystal substrate 1 may be used to manufacture semiconductor devices, which includes a scribe-surface 3 (bottom side) having scribe lines L formed thereon, which is attached to a dicing tape 9 with adhesive property, and a break-surface 2 (top side) opposite to the scribe-surface 3, which is protected by a non-adhesive protecting film 10.

The single-crystal substrate 1 is placed on a breaking table 11 of a breaking device with the scribe-surface 3 as the bottom side attached to the dicing tape 9, and divided by pressing with a breaking plate 13 with a blade 14 at its tip, from the protecting film 10 on the top side. Such cases may cause the following problems.

The entire single-crystal substrate 1 is entirely depressed onto the breaking table 11. Since the back side of the single-crystal substrate 1 is attached to the adhesive dicing tape 9, the single-crystal substrate 1 is difficult to open around a breaking point in the horizontal direction.

This suppresses the single-crystal substrate 1 to be deformed in a “V-shape” and increases load applied by the breaking plate 13 at a portion where the breaking plate 13 pushes to the single-crystal substrate 1, causing chipping on the break-surface 2 (top side) of the breaking plate 13, in which the single-crystal substrate 1 is chipped into small pieces.

For comparison, another method for breaking or dividing a single-crystal substrate 1 is described herein with reference to FIG. 3, which has also been implemented.

As illustrated in FIG. 3, the single-crystal substrate 1 includes a scribe-surface 3 (bottom side) having scribe lines L formed thereon, which is attached to a non-adhesive protecting film 10, and a break-surface 2 (top side) opposite to the scribe-surface 3, which is attached to a dicing tape 9 with adhesive property.

In manufacturing single-crystal semiconductor devices 15, the single-crystal substrate 1 is placed on the breaking table 11 of the breaking device with the non-adhesive protecting film 10 on the bottom side, and divided by pressing with the breaking plate 13 with a blade 14 at its tip, from the top side attached to the dicing tape 9. Such cases may cause the following situations.

The breaking plate 13 pushes to the single-crystal substrate 1 so that the entire single-crystal substrate 1 is deformed and entirely depressed onto the breaking table 11. The back side of the single-crystal substrate 1 is protected by the protecting film 10. Since the protecting film 10 has non-adhesive property, which is not attached to the single-crystal substrate 1, the single-crystal substrate 1 is easy to open around the breaking point in the horizontal direction.

Since the single-crystal substrate 1 is easily deformed into a “V-shape” shape, the load applied by the breaking plate 13 at the portion where the breaking plate 13 pushes to the single-crystal substrate 1 is decreased, reducing the chipping on the break-surface 2 (top side) of the single-crystal substrate 1.

Again, as described above, when the arrangement shown in FIG. 2 is used to divide the single-crystal substrate 1, the single-crystal substrate 1 is chipped into small pieces (caused the chipping) on the break-surface 2 (top side). The chipping scatters small pieces of the chipped single-crystal substrate 1, which causes a problem in subsequent process steps.

For example, the scattered chipped pieces may contaminate the semiconductor devices 15, and the contaminated semiconductor devices 15 cannot be brought into subsequent process equipment. The scattered chipped pieces may easily cause breakdown of electrical insulation in the semiconductor devices 15.

The chipping, in which the single-crystal substrate 1 is chipped into small pieces, is likely caused on the break-surface 2 (top side), especially when the adhesive dicing tape 9, which contacts the breaking table 11, is attached to the scribe-surface (bottom side). Also, the chipping, in which the single-crystal substrate 1 is chipped into small pieces, is likely caused on the break-surface 2 (top side), when the single-crystal substrate 1 is divided along a scribe lines L2 extending in a direction orthogonal to an orientation flat 8.

That is, when the single-crystal substrate 1 is placed on the breaking table 11 for breaking or dividing into pieces of the semiconductor devices 15, the dicing tape 9 attached to the scribe-surface 3 is adhesive, and does not stretch in the horizontal direction, suppressing the single-crystal substrate 1 to be deformed. This causes the problem of the chipping on the break-surface 2 (top side), in which the single-crystal substrate 1 is chipped into small pieces. The present invention is to solve the problem for such a single-crystal substrate 1.

In Patent Document 1, a blade is in contact with the scribe lines at positions opposite to the scribe lines, which may cause the chipping. Patent Document 2 discloses a mother substrate including glass substrates, COS, and intermediate end material, of which objected to be processed is different from those of the present invention. Also in Patent Document 2, the shift of the break bar is 100 μm, which is substantial and may cause chipping.

In view of the above problems, the present invention has an objective to provide a method for breaking or dividing a single-crystal substrate, which can reduce chipping, in which the single-crystal substrate 1 is chipped into small pieces on the break-surface 2 (top side), by shifting a breaking plate by a predetermined amount from a cleavage surface that is defined as a scheduled division line, when breaking or dividing the single-crystal substrate.

### SUMMARY OF THE INVENTION

In order to achieve the above-mentioned objectives, the following technical solutions have been provided in the present invention.

The present invention relates to a process for dividing a single-crystal substrate having a cleavage plane inclined with respect to a scribe-surface and a break-surface of the single-crystal substrate, the process including steps of, forming a scribe line on the scribe-surface, attaching an adhesive dicing tape onto the scribe-surface, inverting and placing the single-crystal substrate on a breaking table such that the scribe-surface faces the breaking table, bringing a breaking plate into contact with the break-surface along a break-line which is positioned away from a cross-line where the cleavage plane extending from the scribe line crosses the break-surface, with respect to a reference line where a vertical plane extending from the scribe line in a direction orthogonal to the scribe-surface and the break-surface crosses the break-surface, and applying external force to the break-surface from the breaking plate to divide the single-crystal substrate along the cleavage plane.

The cleavage plane may be inclined at an off-angle to the vertical plane. A distance (a) between the reference line and the cross-line on the break-surface may be defined as a following equation, wherein the single-crystal substrate has thickness (t) and the off-angle (θ):

a=t×tan θ (1).

The break-line may be positioned away from the cross-line by a predetermined shift distance, with respect to the reference line.

The predetermined shift distance may be determined by the thickness (t) and the off-angle (θ) of the single-crystal substrate.

When the single-crystal substrate has the thickness (t) from 0.1 mm to 0.5 mm and the off-angle (θ) of 4°, the predetermined shift distance may be from 1 μm to 50 μm.

When the thickness (t) of the single-crystal substrate is 0.1 mm and the off-angle (θ) is 4°, the predetermined shift distance may be from 10 μm to 30 μm.

When the thickness (t) of the single-crystal substrate is 0.35 mm and the off-angle (θ) is 4°, the predetermined shift distance may be from 24.5 μm to 50 μm.

When the thickness (t) of the single-crystal substrate is 0.50 mm and the off-angle (θ) is 4°, the predetermined shift distance may be from 35 μm to 50 μm.

The single-crystal substrate may have an orientation-specific component of which shape identifies a crystal orientation of the cleavage plane.

The single-crystal substrate may include an orientation flat. The step of forming the scribe line may include forming a first scribe line extending parallel to the orientation flat, and forming a second scribe line extending perpendicular to the orientation flat. The step of bringing the breaking plate into contact with the break-surface may include bringing the breaking plate into contact with the break-surface along the break-line which is positioned away from the cross-line where the cleavage plane extending from the second scribe line crosses the break-surface, with respect to the reference line where the vertical plane extending from the second scribe line in a direction orthogonal to the scribe-surface and the break-surface crosses the break-surface.

The step of forming the scribe line may include forming a crack extending from the scribe line towards the break-surface. The step of dividing the single-crystal substrate may include dividing the single-crystal substrate along the cleavage plane extending from the crack.

The above and other elements, features, steps, characteristics and advantages of the present invention will become more apparent from the following detailed description of the example embodiments with reference to the attached drawings.

### BRIEF DESCRIPTION OF THE DRAWINGS

A more complete appreciation of example embodiments of the present invention and many of the attendant advantages thereof will be readily obtained as the same becomes better understood by reference to the following detailed description when considered in connection with the accompanying drawings described below.

FIG. 1 is a cross-sectional view of a single-crystal substrate which is to be broken or divided according to one example of a conventional technique.

FIG. 2 is a cross-sectional view of a single-crystal substrate including a scribe-surface (that is a bottom side) which is attached to a dicing tape with adhesive property, and a break-surface (that is a top side) which is protected by a protecting film, illustrating chipping caused on the break-surface when breaking up or dividing the single-crystal substrate.

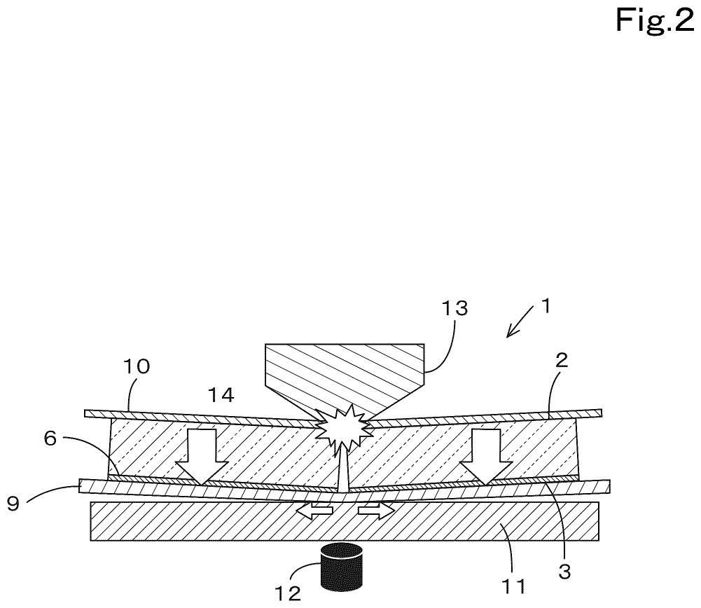

FIG. 3 is a cross-sectional view of a single-crystal substrate including a scribe-surface (that is a bottom side) which is protected to a protecting film and a break-surface (that is a top side) which is attached to a dicing tape with adhesive property, which is to be broken or divided according to another example of a conventional technique.

FIG. 4 is a schematic cross-sectional view of a single-crystal substrate which is to be broken or divided by a dividing process according to the present invention.

FIG. 5 is an enlarged cross-sectional view of a portion (Z) indicated in FIG. 4 including a cleavage plane of the single-crystal substrate, which illustrates how to derive a shift amount of a breaking plate.

FIG. 6 is a graph illustrating a relationship between thickness (t) of the single-crystal substrate and the shift amount (a) of the breaking plate when the single-crystal substrate has an off-angle (θ) of 4°.

FIG. 7 is a perspective view of the single-crystal substrate, from which semiconductor devices are produced.

### DETAILED DESCRIPTION OF THE EXAMPLE EMBODIMENTS

Example embodiments will now be described with reference to the accompanying drawings, wherein like reference numerals designate corresponding or identical elements throughout the various drawings. The drawings are to be viewed in an orientation in which the reference numerals are viewed correctly.

The following describes a process for dividing a single-crystal substrate according to an embodiment of the present invention, with reference to attached drawings. The following embodiment is described as an example, and configuration/arrangement of the present invention is not limited to the embodiment.

First, a semiconductor wafer 1, which is a base material of semiconductor devices 15, and the breaking device are described herein.

The process of the present invention may be suitably used for manufacturing semiconductor devices 15 including power semiconductor devices, high-frequency semiconductor devices, HEMTs (High Electron Mobility Transistors), and other compound semiconductor devices. Note that the semiconductor device 15 may be referred to simply as chips 15.

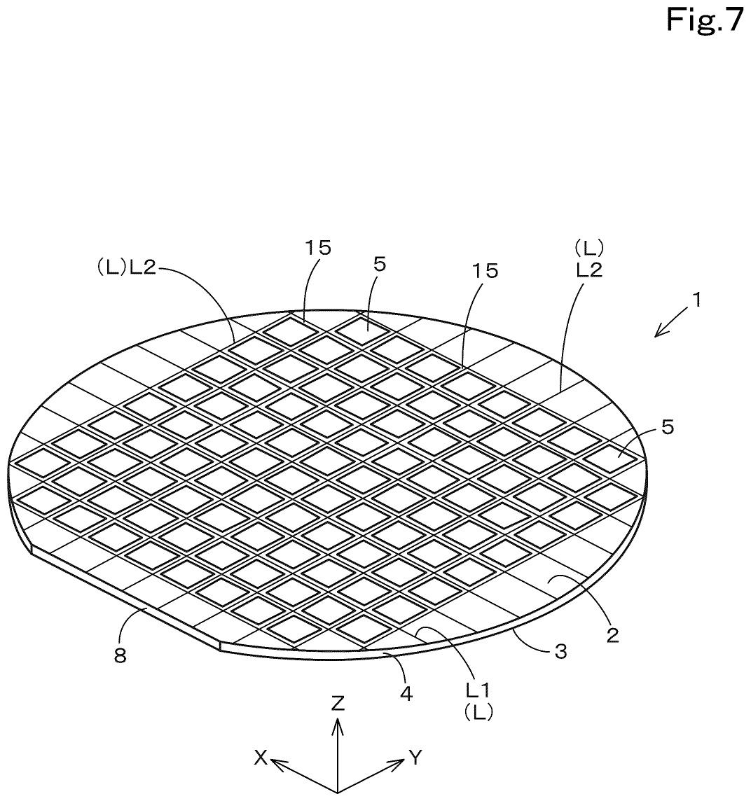

FIG. 7 is a schematic perspective view of a semiconductor wafer 1, which is a substrate of brittle material, according to one embodiment. As an example, the semiconductor substrate 1 (single-crystal semiconductor wafer 1), which is the base material of chips 15, is described herein. The following describes that the single-crystal substrate 1 of the present embodiment is made of 4H-SiC single-crystal having an off-angle, as one example of hexagonal SiC single crystal.

As illustrated in FIG. 7, the single-crystal substrate 1 is disk-shaped and used as the base material for manufacturing the chips 15. The single-crystal substrate 1 has thickness of about 0.5 mm or less.

The single-crystal substrate 1 includes a first wafer main surface 2, a second wafer main surface 3 opposing to the first wafer main surface 2, and a wafer side 4 connecting the first wafer main surface 2 and second wafer main surface 3.

The first wafer main surface 2 faces the {0001} plane (silicon plane (Si-plane)) of the SiC single crystal. A plurality of device-formation areas 5 (mounting surfaces) are formed on the first wafer main surface 2, of which number depends on the chip number.

Note that, in the following description, the first wafer main surface 2 is referred to as a break-surface 2 since it is placed on (it faces) a breaking plate 13 when the single-crystal substrate 1 is broken or divided, and also referred as a pattern-surface 2 since a plurality of device-formation areas 5 are formed thereon.

The second wafer main surface 3 faces the {0001} plane (carbon plane (C-plane)) of the SiC single crystal. The second wafer main surface 3 is the surface (non-mounting surface) which is fixed to a supporting member for supporting the chip 15 that is broken or divided from the single-crystal substrate 1.

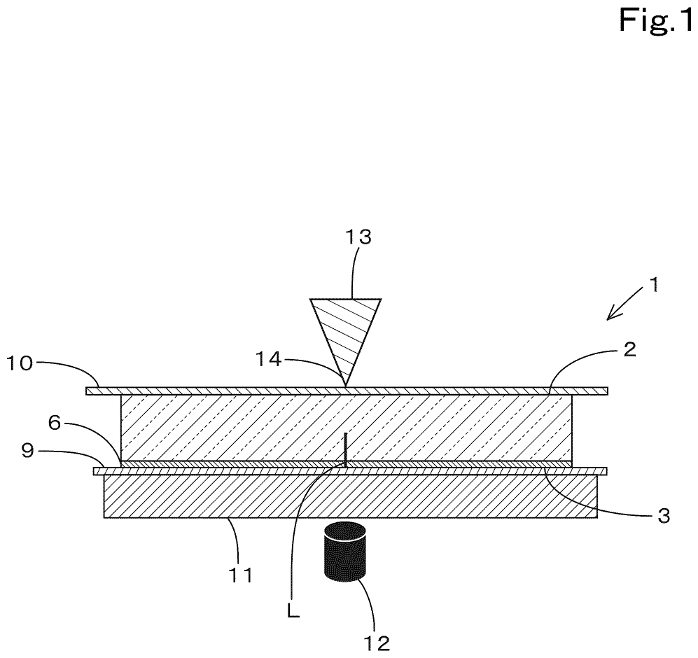

Note that, in the following description, the second wafer main surface 3 is referred to as a scribe-surface since a plurality of scribe lines is formed thereon. The scribe-surface 3 is provided with a bottom electrode layer 6 deposited thereon (cf. FIG. 1). This scribe-surface 3 is also referred to as a metal-surface. Thus, the single-crystal substrate 1 includes the break-surface 2 and the scribe-surface 3 which oppose each other.

The wafer side 4 is provided with a notch 8. The notch 8 is referred to as an orientation flat (OF), which indicates a crystal orientation of the SiC single-crystal substrate. For example, one or two of the orientation flats 8 may be provided. The single-crystal substrate 1 is broken or divided into a plurality of chips 15 (SiC semiconductor devices 15).

Scribe-lines L1 are formed on the single-crystal substrate 1 extending in the X-axis direction which is parallel to the orientation flat 8.

Scribe-lines L2 are formed on the single-crystal substrate 1 extending in the Y-axis direction which is orthogonal to the orientation flat 8. When the single-crystal substrate 1 is divided and cleaved by crack propagation extending from the scribe-line L2, the side (surface) of the chip 15 is formed on the SiC single-crystal crystal plane (cleavage plane 7).

The single-crystal substrate 1 includes the scribe-surface 3 (C-plane 3), on which the scribe lines L1 and L2 are formed in a grid pattern, and the scribe-surface 3 is attached to a dicing tape 9 at a center portion thereof, which is stretched over an annular ring member (dicing ring). The single-crystal substrate 1 includes the break-surface 2 (Si-plane) opposing to the scribe-surface 3 (C-plane 3), which is protected by a protecting film 10.

The single-crystal substrate 1 configured as above and objected to be divided is mounted on the breaking table 11 of the breaking device, of which scribe-surface 3 attached to the dicing tape 9 faces downward.

The following briefly describes one example of configuration of the breaking device that breaks up or divides the single-crystal substrate 1 including the scribe lines L formed thereon.

The breaking device breaks up the single-crystal substrate 1 into chips 15 (unit piece substrate) by pushing the breaking plate 13 along each of the scribe lines L from above onto the break-surface 2 against the single-crystal substrate 1 on which a scribing device has formed the scribe lines L.

The breaking device includes a breaking table 11 on which a single-crystal substrate 1 that is objected to be broken or divided is seated, a breaking plate 13 provided in a suspended manner over the breaking table 11, which breaks up or divides the single-crystal substrate 1 seated on the breaking table 11 along the scribe lines L. The breaking device also includes a beam oscillator which is provided above to cover the breaking table 11, oscillating a beam having a flat-top file intensity distribution. The breaking table 11 is configured to rotate around an axis extending in a Z-axis direction, as the rotation axis, for example.

The breaking plate 13 (breaking bar 13) is an elongated member extending in the X-axis direction. The breaking plate 13 includes a tip (bottom edge) having a straight ridge (blade 14) to divide the single-crystal substrate 1 along the scribe lines L1 and L2.

The breaking plate 13 breaks up or divides the single-crystal substrate 1 into the chips 15 along each of the scribe lines L1 in the X-axis direction and scribe lines L2 in the Y-axis direction while the breaking table 11 rotates around the Z-axis direction.

The breaking plate 13 is configured to be raised or lowered in the Z-axis direction relative to the beam oscillator by means of an elevation mechanism. Note that, a receiving blade may be provided beneath the breaking plate 13 as one of a pair of blades, which receives against the depressing force from the breaking plate 13 when the breaking plate 13 pushes downward to break up or divide the single-crystal substrate 1.

Configuration and/or arrangement of the breaking device is not limited thereto as illustrated above. For example, the breaking plate 13 may be rotatable around an axis extending in the Z-axis direction as the rotation axis. The breaking device may also include a first breaking plate that divides the single-crystal substrate 1 along the scribe lines L1 in the X-axis direction and a second breaking plate that divides the single-crystal substrate 1 along the scribe lines L2 in the Y-axis direction.

The following describes a process to divide the single-crystal substrate 1 into chips 15 by means of the breaking device provided with the breaking table.

As illustrated in FIG. 1, the single-crystal substrate 1 includes the scribe-surface 3 (C-plane 3) which is attached to an adhesive dicing tape 9 (wafer fixing tape), and the break-surface 2 (Si-plane 2) opposing to the scribe-surface 3, which is protected by a non-adhesive (including a slightly adhesive) protecting film 10. Thus, the single-crystal substrate 1 has a top side kept in an unbound state on the protecting film 10.

The single-crystal substrate 1 is placed on the breaking table 11 with a bottom of the single-crystal substrate 1 attached to the dicing tape 9. A camera 12 is provided below the breaking table 11, which is configured to detect the scribe lines L formed on the single-crystal substrate 1.

The breaking plate 13 having a blade 14 at its tip is lowered onto and brought into contact with the single-crystal substrate 1 from the break-surface 2 or the top side opposing to the scribe lines L, and further pushed downward with an external force to break or divide the single-crystal substrate 1 into semiconductor devices.

Specifically, the breaking plate 13 is lowered such that the blade 14 provided at its tip is pressed along the scribe line L1 in the X-axis direction (parallel to orientation flat 8) from the break-surface 2 (pattern-surface 2) to break up or divide the single-crystal substrate 1, and then the breaking plate 13 is raised.

Thereafter, the breaking table 11 is rotated 90° around the Z-axis, and the breaking plate 13 is lowered such that the blade 14 at its tip is pressed along the scribe line L2 in the Y-axis direction (orthogonal to the orientation flat 8) from the surface break face 2 to break up or divide the single-crystal substrate 1.

The breaking table 11 is rotated 90° around the Z axis, and the blade 14 of the breaking plate 13 is pressed against all scribe lines L1 and L2 formed in a lattice-shaped configuration to break up or divide the single-crystal substrate 1 into a plurality of chips 15 as illustrated in FIG. 7.

After the step of breaking, the single-crystal substrate 1 is retrieved from the breaking table 11 and delivered to the subsequent step. Each of the chips 15 produced from the single-crystal substrate 1 contains a SiC semiconductor layer, for example, and is about 5 mm×5 mm in size.

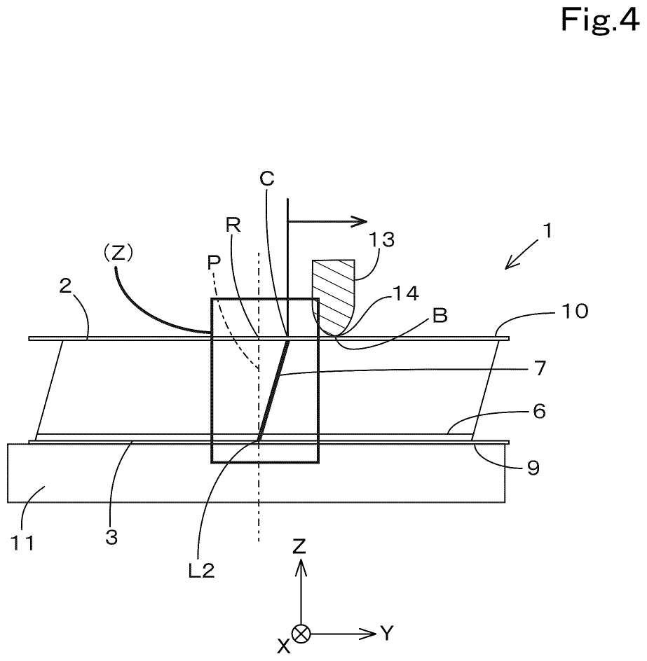

FIG. 4 is a schematic cross-sectional view of the single-crystal substrate which is to be broken or divided by a dividing process according to the present invention.

As illustrated in FIG. 4, the present invention is a technique applicable to a manufacturing process of the semiconductor devices 15 (chips 15), by forming the scribe lines L on the single-crystal substrate 1 and then applying an external force along the scribe lines L from the breaking plate 13 to break up or divide the single-crystal substrate 1 into semiconductor devices 15 (chips 15).

The single-crystal substrate 1 subject to the present invention includes at least the scribe-surface 3 (C-plane 3, i.e., the scribe-surface 3 that is a bottom surface when the substrate 1 is placed on the breaking table 11), which is attached to the adhesive dicing tape 9 (adhesive film). Thus, the single-crystal substrate 1 is held by the adhesive dicing tape 9.

On the other hand, the break-surface 2, which is the top side opposite the bottom side or scribe-surface 3, is protected by a protecting film 10 (regardless of whether to be adhesive). The single-crystal substrate 1 subject to the present invention has thickness (t) of 0.5 mm or less.

The single-crystal substrate 1 is placed on the breaking table 11 so that the scribe-surface 3 attached to the dicing tape 9 is in contact with (or faces) the breaking table 11. The breaking plate 13 is used to apply an external force along each of the scribe lines L from the break-surface 2 (Si-plane 2, i.e., the break-surface 2 that is a top side when the substrate 1 is placed on the breaking table 11), to break up or divide the single-crystal substrate 1.

Specifically, when breaking up or dividing the single-crystal substrate 1 along the scribe line L2 extending in a direction orthogonal to the orientation flat (OF) 8 provided with the single-crystal substrate 1, the contact position of the breaking plate 13 where the breaking plate 13 contacts the single-crystal substrate 1 is shifted away from an inclined cleavage plane 7 (scheduled-division line) on the break-surface 2, which is formed as crack propagation extending from the scribe line L2 in the direction orthogonal to the orientation flat (OF) 8.

In other words, as illustrated in FIG. 4, the contact position of the breaking plate 13 onto the break-surface 2 of the single-crystal substrate 1 is shifted away from the scribe line L2 in the direction orthogonal to the orientation flat 8 to the scheduled-division line which is to be cleaved by the crack propagation (in the direction to which the cleavage plane 7 is inclined).

Now, the following describes a situation or phenomenon which occurs when the single-crystal substrate 1 subject to the present invention is divided by a conventional technique. Thus, such a situation or phenomenon may appear when dividing the single-crystal substrate 1 including the scribe-surface 3 (bottom surface) attached to the dicing tape 9, and the break-surface 2 (top side) attached to the protecting film 10.

Specifically, when breaking up or dividing the single-crystal substrate 1 by adopting the conventional step to break the single-crystal substrate 1 at the breaking position along the scribe line L2 that extends in the direction orthogonal to orientation flat 8, the chipping is likely occurred on the break-surface 2 (top side, pattern-surface 2), in which the single-crystal substrate 1 breaks into small pieces on the break-surface 2 thereof, due to a relationship between the breaking plane {11-20} (cleavage plane 7) formed by crack propagation from the scribe line L2 that extends in the direction orthogonal to the orientation flat 8 and the {0001} plane, which is another cleavage plane of the single-crystal substrate 1. The chipping scatters the small pieces of the chipped single-crystal substrate 1, which causes a problem in subsequent steps.

To solve the problem, when dividing the single-crystal substrate 1 along the scribe line L2 extending in the direction orthogonal to the orientation flat 8, the contact position of the breaking plate 13 is shifted away from the scheduled-division line (cleavage plane 7) as illustrated by an arrow indicating the shift direction in FIG. 4. Note that, the scheduled-division line is intended to be a “plane” in the Y-Z plane shown in FIG. 4, that extends across the X-direction and in parallel to the cleavage plane 7 in which the crack extends from the scribe line L2 to the break-surface 2, however, the present description conveniently refers to the scheduled-division line as a “line”.

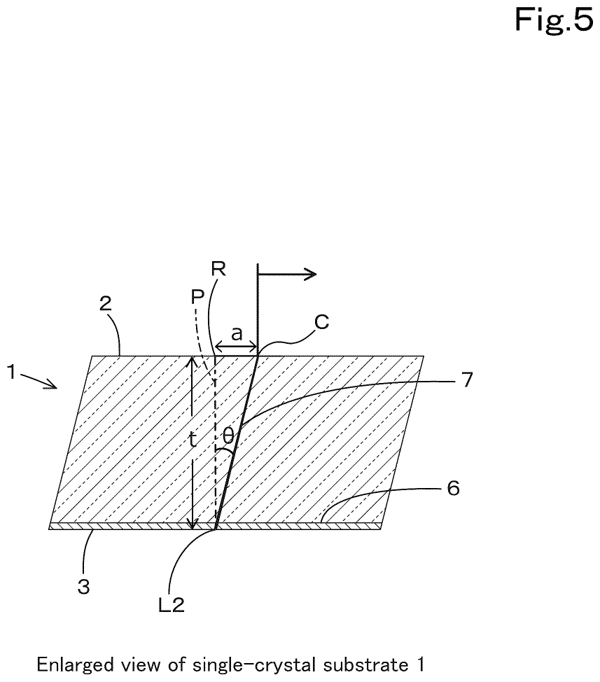

In other words, when breaking up the single-crystal substrate 1, the breaking plate 13 may be in contact with or displaced on the break-surface 2 in the direction away from the cleavage plane 7 (right side in FIGS. 4 and 5, the direction in which the cleavage plane 7 is inclined), which is cleaved by the crack formed beneath the scribe line L2 extending in the direction orthogonal to the orientation flat 8.

In more detail, in the above step of forming the scribe lines L on the single-crystal substrate 1, the single-crystal substrate 1 is formed with scribe lines, including first scribe lines L1 each extending in a direction parallel to the orientation flat 8 (the X-axis direction shown in FIG. 7) and a second scribe lines L2 each extending in a direction orthogonal to the orientation flat 8 (the Y-axis direction shown in FIG. 7).

The single-crystal substrate 1 is formed with a vertical plane P and a reference line R as illustrated in FIG. 5. The vertical plane P extends from the second scribe line L2, which is perpendicular to the break-surface 2 and the scribe-surface 3. The reference line R is a line where the vertical plane P intersects the break-surface 2. The vertical plane P and the reference line R are virtual, extending in a depth direction of FIG. 5 (X-axis direction in FIG. 7). That is, the cleavage plane 7 of the single-crystal substrate 1 is inclined at an off-angle θ with respect to the vertical plane P in the Y-Z cross-section of FIG. 7.

As illustrated in FIG. 5, a cross-line C is virtually defined where the cleavage plane 7 of the single-crystal substrate 1 intersects the break-surface 2, and a distance (a) is virtually defined between the reference line R and the cross-line C in the Y-Z cross-section. In the above step of shifting and positioning the breaking plate 13, it could be considered ideal to bring the breaking plate 13 into contact with the break-surface 2 at a position (along a straight line extending in the X-axis direction, i.e., at the cross-line C) which is away from the reference line R by a distance calculated by the equation (1) described below. However, the inventors of the present invention have confirmed that the chipping can be suppressed by placing the breaking plate 13 on the break-line B (FIG. 4) in the direction further away from the cross-line C (displaced from the cross-line C), with respect to the reference line R, and applying an external force to break up or divide the single-crystal substrate 1 into the semiconductor devices 15 (chips 15).

Thus, as illustrated in FIG. 4, the inventor has confirmed that shifting the breaking plate 13 away from the cross-line C (e.g., along the break-line B) in the direction of the crack extension from the scribe line L2 that is orthogonal to the orientation flat 8, tends to reduce the chipping which are small pieces chipped from the single-crystal substrate 1 on the break-surface 2 (pattern-surface 2, top side), rather than placing the breaking plate 13 along the cross-line C where the chip 15 is considered broken up along the cleavage plane 7 with the off-angle.

The contact position of the breaking plate 13 on the single-crystal substrate 1 may be offset from the scribe line L2 that is orthogonal to the orientation flat 8 in the extension direction of the cleavage plane 7 of the single-crystal substrate 1 (away from the direction in which the cleavage plane 7 is inclined).

Some examples are illustrated herein for numerical ranges of distance (a) by which the breaking plate 13 is shifted horizontally from the orthogonal scribe line L2.

For example, when the single-crystal substrate 1 has thickness (t) of 0.1 mm and the off-angle (θ) of 4°, the shift distance (a) of the breaking plate 13 may be in the range of 1 μm to 50 μm. Preferably, the shift distance (a) of the breaking plate 13 may be in the range of 10 μm to 30 μm.

When the single-crystal substrate 1 has thickness (t) of 0.35 mm and the off-angle (θ) of 4°, the shift distance (a) of the breaking plate 13 may be in the range of 1 μm to 50 μm. Preferably, the shift distance (a) of the breaking plate 13 may be in the range of 25 μm to 50 μm.

The following discusses numerical ranges of the shift amount (a) in which the breaking plate 13 (blade 14) is to be shifted away from the orthogonal scribe line L2 in the direction of the orthogonal scribe line L2 on the break-surface 2.

FIG. 5 is an enlarged cross-sectional view of a portion (Z) including the cleavage plane 7 of the single-crystal substrate 1 of FIG. 4, which illustrates how to derive the shift amount of the breaking plate 13.

As illustrated in FIG. 5, the following equation (1) can be used to calculate the shift amount (a) of the breaking plate 13 at a scheduled division line (cleavage plane 7 or cross-line C) on the break-surface 2 (Si-plane 2) from the position (reference line R) of the scribe line L2 extending in a direction orthogonal to the orientation flat 8, based on the thickness (t) and the off-angle (θ) of the single-crystal substrate 1.

a=t×tan θ (1)

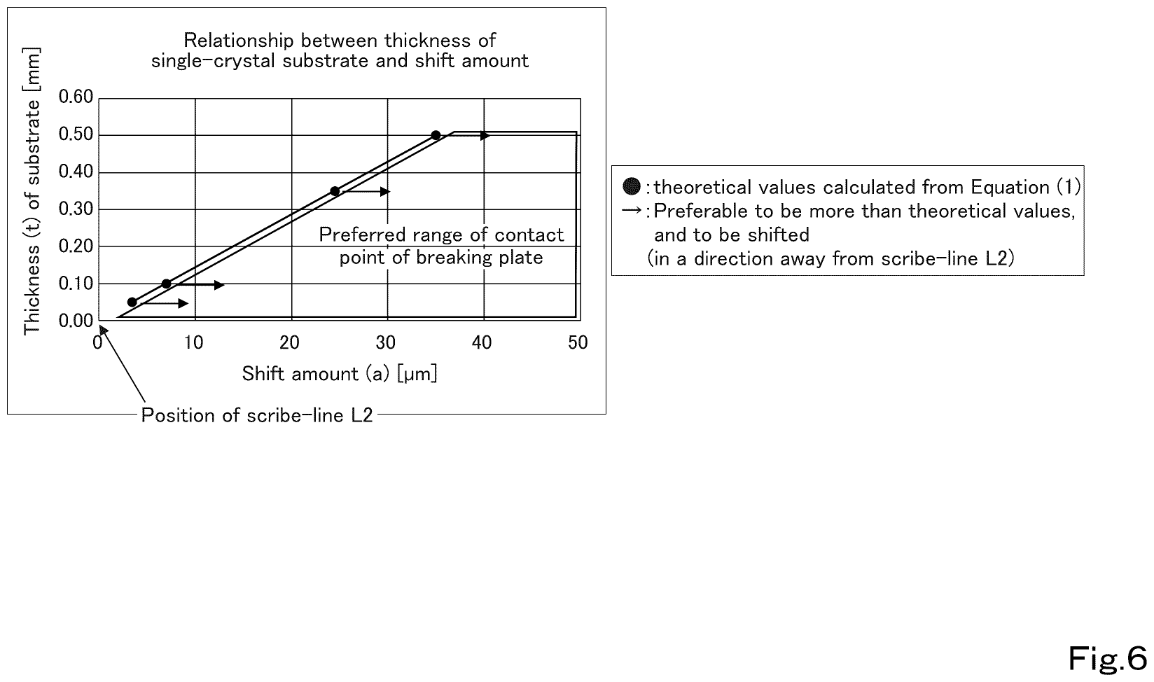

FIG. 6 is a graph illustrating a relationship between thickness (t) of the single-crystal substrate 1 and the shift amount (a) of the breaking plate 13 when the single-crystal substrate 1 has the off-angle (θ) of 4°. The black circles dotted in FIG. 6 indicate theoretical values of the shift amount (a) calculated from the equation (1). Note that, however, the present invention covers single-crystal substrates 1 having thickness (t) of 0.5 mm or less. The shift amount in the present invention is intended to a “shift distance” between the reference line R and the break-line B in the Y-Z cross section of FIG. 4. According to the present invention, as explained above, the chipping can be suppressed by extending the shift distance of the breaking plate 13 larger (a+α) than the theoretical value (a) calculated by the equation (1).

As illustrated in FIG. 6, for example, when the single-crystal substrate 1 has thickness (t) of 0.05 mm, the shift amount (a) calculated by the equation (1) is about 3.496 μm. Thus, when the single-crystal substrate 1 has the thickness (t) of 0.05 mm, the shift distance between the reference line R and the break-line B may be set within the range of 3.5 μm to 50 μm.

When the single-crystal substrate 1 has the thickness (t) of 0.1 mm, the shift amount (a) calculated by the equation (1) is about 6.992 μm. Thus, when the single-crystal substrate 1 has the thickness (t) of 0.1 mm, the shift distance between the reference line R and the break-line B may be set within the range of 7 μm to 50 μm.

When the single-crystal substrate 1 has the thickness (t) of 0.35 mm, the shift amount (a) calculated by the equation (1) is about 24.474 μm. Thus, when the single-crystal substrate 1 has the thickness (t) of 0.35 mm, the shift distance between the reference line R and the break-line B may be set within the range of 24.5 μm and 50 μm.

When the single-crystal substrate 1 has the thickness (t) of 0.5 mm, the shift amount (a) calculated by the equation (1) is about 34.963 μm. Thus, when the single-crystal substrate 1 has the thickness (t) of 0.5 mm, the shift distance between the reference line R and the break-line B may be set within the range of 35 μm and 50 μm.

As described above, the inventors of the present invention have confirmed that it is preferable to shift the breaking plate 13 in the inclined direction of the cleavage plane 7 (direction away from the reference line R), by the shift distance which is larger than the theoretical value of the shift amount (a) (see, arrows and a trapezoidal area as illustrated in FIG. 6).

Thus, it is preferable to shift the breaking plate 13 horizontally away from the scribe line L2 on the break-surface 2 of the single-crystal substrate 1, in the direction orthogonal to the orientation flat 8 by the shift distance which is equal to or larger than the shift amount (a) calculated by the equation (1).

In other words, the breaking plate 13 may be shifted to the position from the reference surface R by the shift value (a) calculated by the equation (1) or more in a direction such that an angle between the break-surface 2 and the cleavage plane 7 is larger.

The breaking plate 13 may be shifted by the shift amount (a) calculated by the equation (1) or more beyond the cross-line C (scheduled division position) where the cleavage plane 7 and the break-surface 2 intersect and the single-crystal substrate 1 is divided along the cleavage plane 7, away from the scribe line L2 (reference line R) in the inclined and orthogonal direction of the cleavage plane 7.

As discussed above, the shift amount (a) of the breaking plate 13 to be shifted horizontally is determined by the equation (1), for example, depending on the thickness (t) and the off angle (θ) of the single-crystal substrate 1.

Meanwhile, the inventors of the present invention have confirmed that the shift amount (a) of the breaking plate 13 exceeding 50 μm arises problems, which is not suitable. That is, the breaking plate 13 shifted substantially to the right side in FIG. 4 may cause the chipping, which is not suitable. The inventors of the present invention have also confirmed that it is not suitable with substantial chippings caused when the breaking plate 13 is shifted towards the left direction of FIG. 4 where the breaking plate 13 is positioned at the left side of the scribe line L2, with respect to the cross-line C where the cleavage plane 7 and break-surface 2 intersect.

Thus, the contact position of the breaking plate 13 onto the break-surface 2 of the single-crystal substrate 1 may be displaced away from the scribe line L2 extending towards the inclined direction of the cleavage plane 7, by the shift amount (a) calculated by the equation (1) or more, with respect to the cleavage plane 7 (scheduled-division line) which is formed as crack propagation extending from the scribe line L2 in the direction orthogonal to the orientation flat (OF) 8.

Note that however, the off-angle of the single-crystal substrate 1 does not affect the division thereof along the scribe line L1 extending in the direction parallel to the Orientation Flat (OF) 8, allowing the division of the single-crystal substrate 1, without any problem, in a direction vertical or orthogonal to the scribe-surface 3 and the break-surface 2. Thus, there is no need to shift the contact position of the breaking plate 13 on the break-surface 2.

Note that, the single-crystal substrate 1 may be formed with cracks extending along the cleavage planes 7 in the step of forming the scribe lines L1 and L2, to cleave and divide the single-crystal substrate 1 due to the crack propagation along the cleavage planes 7.

In the above description, the single-crystal substrate 1 includes an orientation flat (OF) 8 as an orientation-specific component that identifies a crystal orientation of the cleavage plane 7 by configuration, however, it is not limited thereto. The orientation-specific components need only to have a shape identifying the crystal orientation of the cleavage plane 7, which may have other configurations including a notch.

It is preferable that the scribe-surface 3 (metal-surface 3, bottom side) of the single-crystal substrate 1 is attached to the adhesive dicing tape 9.

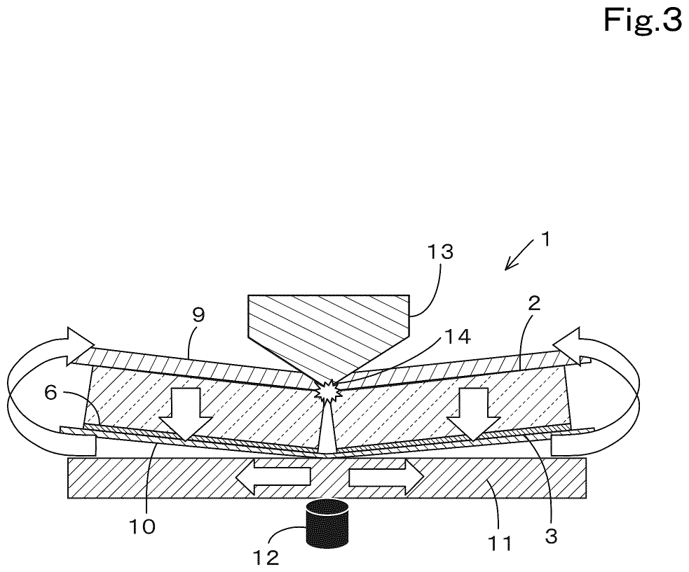

As described above with reference to FIG. 3, the chipping is less on the break-surface 2 where the single-crystal substrate 1 includes the scribe-surface 3 covered with the non-adhesive protecting film 10.

The protecting film 10 attached to the break-surface 2 (pattern-surface 2, top side) may or may not have adhesive property.

As described above, the present invention provides a process for dividing a single-crystal substrate 1, which includes shifting the breaking plate 13 by a predetermined shift amount (a) from the cleavage plane 7 (scheduled-division line) towards the inclined direction thereof, when breaking the single-crystal substrate 1 along the scribe line L, especially when breaking the single-crystal substrate 1 along a scribe line L2 in the direction orthogonal to the orientation flat 8, thereby to suppress the chipping which are small pieces chipped from the single-crystal substrate 1 on the break-surface 2 (pattern-surface 2, top side).

According to the chipping-reduction process for dividing the single-crystal substrate 1 including offset-breaking by the breaking plate 13, the yield of the chips 15 produced from the single-crystal substrate 1 can be enhanced. Thus, it is possible to efficiently manufacture the chips 15 which are to be semiconductor products.

Note that, the embodiments disclosed herein should be considered illustrative and not restrictive in views of all aspects. In particular, matters not explicitly stated in the embodiments, including for example, operating conditions, dimensions and weight of the components, do not depart from the scope of ordinary practice by those skilled in the art, which can be readily adopted by those having an ordinary skill in the art.

In the present embodiment, an example of a 4H (Hexagonal)-SiC single-crystal with an off-angle of 4° is described for in the single-crystal substrate 1 as an example of hexagonal SiC single-crystal substrates. Si single-crystal substrates and SiC hexagonal single-crystal substrates with the off-angle are applicable to the present invention. 2H-SiC single-crystal or 6H-SiC single-crystal substrates are also applicable to the present invention.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A process for dividing a single-crystal substrate having a cleavage plane inclined with respect to a scribe-surface and a break-surface of the single-crystal substrate, the process including steps of:
forming a scribe line on the scribe-surface;
attaching an adhesive dicing tape onto the scribe-surface;
inverting and placing the single-crystal substrate on a breaking table such that the scribe-surface faces the breaking table;
bringing a breaking plate into contact with the break-surface along a break-line which is positioned away from a cross-line where the cleavage plane extending from the scribe line crosses the break-surface, with respect to a reference line where a vertical plane extending from the scribe line in a direction orthogonal to the scribe-surface and the break-surface crosses the break-surface; and
applying external force to the break-surface from the breaking plate to divide the single-crystal substrate along the cleavage plane.

2. The process for dividing the single-crystal substrate according to claim 1, wherein
the cleavage plane is inclined at an off-angle to the vertical plane,
a distance (a) between the reference line and the cross-line on the break-surface is defined as a following equation, wherein the single-crystal substrate has thickness (t) and the off-angle (θ),
a=t×tan θ (1).

3. The process for dividing the single-crystal substrate according to claim 1, wherein
the break-line is positioned away from the cross-line by a predetermined shift distance, with respect to the reference line.

4. The process for dividing the single-crystal substrate according to claim 3, wherein
the predetermined shift distance is determined by the thickness (t) and the off-angle (θ) of the single-crystal substrate.

5. The process for dividing the single-crystal substrate according to claim 3, wherein
when the single-crystal substrate has the thickness (t) from 0.1 mm to 0.5 mm and the off-angle (θ) of 4°, the predetermined shift distance is from 1 μm to 50 μm.

6. The process for dividing the single-crystal substrate according to claim 5, wherein
when the thickness (t) of the single-crystal substrate is 0.1 mm and the off-angle (θ) is 4°, the predetermined shift distance is from 10 μm to 30 μm.

7. The process for dividing the single-crystal substrate according to claim 5, wherein
when the thickness (t) of the single-crystal substrate is 0.35 mm and the off-angle (θ) is 4°, the predetermined shift distance is from 24.5 μm to 50 μm.

8. The process for dividing the single-crystal substrate according to claim 5, wherein
when the thickness (t) of the single-crystal substrate is 0.50 mm and the off-angle (θ) is 4°, the predetermined shift distance is from 35 μm to 50 μm.

9. The process for dividing the single-crystal substrate according to claim 1, wherein the single-crystal substrate has an orientation-specific component of which shape identifies a crystal orientation of the cleavage plane.

10. The process for dividing the single-crystal substrate according to claim 1, wherein
the single-crystal substrate includes an orientation flat;
the step of forming the scribe line includes
forming a first scribe line extending parallel to the orientation flat, and
forming a second scribe line extending perpendicular to the orientation flat,
the step of bringing the breaking plate into contact with the break-surface includes
bringing the breaking plate into contact with the break-surface along the break-line which is positioned away from the cross-line where the cleavage plane extending from the second scribe line crosses the break-surface, with respect to the reference line where the vertical plane extending from the second scribe line in a direction orthogonal to the scribe-surface and the break-surface crosses the break-surface.

11. The process for dividing the single-crystal substrate according to claim 1, wherein
the step of forming the scribe line includes forming a crack extending from the scribe line towards the break-surface; and
the step of dividing the single-crystal substrate includes dividing the single-crystal substrate along the cleavage plane extending from the crack.
